(19) United States
(12) Patent Application Publication
(10) Pub. No.: US 2026/0205080 A1
(43) Pub. Date: Jul. 16, 2026

(54) OPERATIONAL AMPLIFIER

(71) Applicant: ROHM CO., LTD., Kyoto-shi (JP)

(72) Inventor: Naohiro NOMURA, Kyoto-shi (JP)

(21) Appl. No.: 19/449,998

(22) Filed: Jan. 15, 2026

(30) Foreign Application Priority Data
Jan. 15, 2025 (JP) 2025-005785

(51) Int. Cl. H03F 3/45; G05F 1/56

(52) U.S. Cl. CPC H03F 3/45475; G05F 1/56

(57) ABSTRACT

An input stage includes a differential pair and an active load. An output stage includes an output transistor that receives an output signal of the input stage. A phase-compensation circuit supplies a feedback current to the active load in accordance with an output voltage. An offset-cancellation circuit supplies a correction current to the active load in accordance with an input voltage of an operational amplifier.

### CROSS REFERENCE TO RELATED APPLICATIONS

The present invention claims priority under 35 U.S.C. § 119 to Japanese Application No. 2025-005785, filed on Jan. 15, 2025, the entire contents of which being incorporated herein by reference.

### BACKGROUND

### 1. Technical Field

This disclosure relates to an operational amplifier.

### 2. Description of the Related Art

Operational amplifiers are among the most important fundamental components in analog circuits. They are used as amplifiers for small-signal and large-signal applications, buffer circuits, regulators, and also as error amplifiers in feedback systems.

In conventional operational amplifiers designed for small-signal amplification applications, a capacitive load causes a phase delay. Depending on the amplifier type, oscillation or poor settling behavior often occurs with a capacitive load on the order of several hundred picofarads.

In some applications, such as reference-voltage source buffers and low-dropout (LDO) amplifiers, steep voltage variations or transient current loads are applied to the output. A large capacitance on the order of microfarads is coupled to the output to stabilize the output voltage in such cases, and high tolerance to a large load capacitance is required.

When a negative feedback circuit is added in order to improve stability against a load capacitance, the offset voltage of the operational amplifier may increase.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures.

FIG. 1 is a circuit diagram of an operational amplifier according to a comparative technique.

FIG. 2 is a circuit diagram of as non-inverting amplifier using the operational amplifier.

FIG. 3 is a diagram showing frequency characteristics of gain and phase of the non-inverting amplifier of FIG. 2.

FIG. 4 is a circuit diagram of an operational amplifier according to one embodiment.

FIG. 5 is a diagram showing frequency characteristics of a conventional non-inverting amplifier.

FIG. 6 is a circuit diagram of a non-inverting amplifier using an operational amplifier.

FIG. 7 is a diagram showing frequency characteristics of the non-inverting amplifier of FIG. 6.

FIG. 8 is a diagram showing frequency characteristics of a second current Is and a third current Ifb.

FIG. 9 is a diagram showing frequency characteristics of the output voltage of the non-inverting amplifier according to the comparative technology and the non-inverting amplifier according to the embodiment, respectively.

FIG. 10 is a circuit diagram of an offset-cancellation circuit according to one embodiment.

FIG. 11 is a diagram illustrating an operation of the offset-cancellation circuit of FIG. 10.

FIG. 12 is a diagram showing a relationship between a common-mode input voltage and an offset voltage of a non-inverting amplifier.

FIG. 13 is a diagram showing frequency characteristics of a non-inverting amplifier using the operational amplifier.

FIG. 14 is a circuit diagram of an offset-cancellation circuit according to a first modification.

FIG. 15 is a circuit diagram of an offset-cancellation circuit according to a second modification.

FIG. 16 is a circuit diagram of an operational amplifier according to one embodiment.

FIG. 17 is a circuit diagram of an operational amplifier according to Embodiment 1.

FIG. 18 is a circuit diagram of an operational amplifier according to Embodiment 2.

FIG. 19 is a circuit diagram of an operational amplifier according to Embodiment 3.

FIG. 20 is a circuit diagram of an operational amplifier according to Embodiment 4.

FIG. 21 is a circuit diagram of an operational amplifier according to Embodiment 5.

FIG. 22 is a circuit diagram of an operational amplifier according to Embodiment 6.

### DETAILED DESCRIPTION

### Overview of the Embodiments

An outline of several example embodiments of the disclosure follows. This outline is provided for the convenience of the reader to provide a basic understanding of such embodiments and does not wholly define the breadth of the disclosure. This outline is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

An operational amplifier according to one embodiment comprises: an input stage having a differential pair, a tail current source, and an active load; an output stage including an output transistor coupled to receive an output signal of the input stage; a phase-compensation circuit structured to supply a feedback current to the active load in accordance with an output voltage of the operational amplifier; and an offset-cancellation circuit structured to supply a correction current to the active load in accordance with an input voltage of the operational amplifier.

According to this configuration, in a frequency domain, negative feedback is applied so as to suppress a variation in an output voltage caused by a gain peak, by supplying to the active load the feedback current corresponding to the variation in the output voltage caused by the gain peak. As a result, the gain peak can be suppressed and a phase rotation can be reduced, thereby improving stability with respect to a capacitive load. Furthermore, a DC component included in the feedback current of the phase-compensation circuit can be canceled by the correction current, thereby suppressing an offset voltage caused by the DC component of the feedback current.

In this specification, the phrase that signal A “is based on” signal B means that signal A has a correlation with signal B, as long as the correlation is of a form and degree that enables the effects of the present disclosure to be obtained. For example, signal A may have a positive correlation with signal B or may have a negative correlation with signal B, which may be inverted depending on the circuit configuration. Furthermore, signal A may vary linearly with respect to signal B or may vary nonlinearly.

In one embodiment, the active load may include a current mirror circuit and a pair of resistors connected to source side of the current mirror circuit. A feedback current may be supplied to a source node of one transistor of the current mirror circuit, and a correction current may be supplied to a source node of another transistor of the current mirror circuit.

In one embodiment, the active load may include a current mirror circuit and a pair of resistors connected to source side of the current mirror circuit. The feedback current may be supplied to a drain node of one transistor of the current mirror circuit, and the correction current may be supplied to a drain node of another transistor of the current mirror circuit.

In one embodiment, the offset-cancellation circuit may include a common-mode voltage detection circuit structured to convert the input voltage of the operational amplifier into a current signal, and a correction-current generation circuit structured to generate the correction current in accordance with the current signal.

In one embodiment, the common-mode voltage detection circuit may include: a first MOS transistor and a second MOS transistor having their gates coupled to an input terminal of the operational amplifier and having their sources coupled to each other and their drains coupled to each other; and a third MOS transistor having its source coupled to the sources of the first MOS transistor and the second MOS transistor, and having a bias voltage supplied to its gate in common with a tail current source. When a common-mode input voltage varies, a source voltage of the first MOS transistor, that is, a drain-to-source voltage of the third MOS transistor, varies. Therefore, due to a channel-length modulation effect, a current flowing through the third MOS transistor varies substantially linearly with respect to the input voltage.

In one embodiment, the correction-current generation circuit may include a current mirror circuit having its input connected to drains of the first MOS transistor and the second MOS transistor, the current mirror circuit being structured to mirror and output a current flowing through the third MOS transistor, and a constant current source. The correction current may be based on a difference between a current generated by the constant current source and an output current of the current mirror circuit.

In one embodiment, the operational amplifier circuit may further include an output variation detection circuit coupled to an output terminal of the operational amplifier and structured to generate a first current in accordance with an output voltage produced at the output terminal. The phase-compensation circuit may supply a second current to the output terminal in accordance with a gate voltage of the output transistor, and may supply a third current to the active load as the feedback current in accordance with the second current.

In one embodiment, the phase-compensation circuit may be structured to adjust an amount of a third current relative to an amount of a second current. By optimizing the amount of the third current, a gain peak can be suitably suppressed.

In one embodiment, the phase-compensation circuit may include a replica transistor of the same type as the output transistor, the replica transistor having its gate coupled to a gate of the output transistor and its source grounded, and a current source connected to a drain of the replica transistor. The second current and the third current may be generated in accordance with a drain voltage of the replica transistor.

In one embodiment, the phase-compensation circuit may include a first transistor having its gate supplied with a drain voltage of the replica transistor and having its source grounded, and a first current mirror circuit having its input connected to a drain of the first transistor to mirror a current flowing through the first transistor and generate the second current.

In one embodiment, the phase-compensation circuit may include a second transistor having its gate supplied with a drain voltage of the replica transistor and having its source grounded, and a second current mirror circuit having its input connected to a drain of the second transistor to mirror a current flowing through the second transistor and generate the third current.

In one embodiment, the output-voltage monitoring circuit may include a resistor disposed between an output terminal of the operational amplifier and a ground line, or between the output terminal of the operational amplifier and a power-supply line.

In one embodiment, the operational amplifier may be monolithically integrated on a single semiconductor substrate. The term “monolithically integrated” includes a case where all components of a circuit are formed on the semiconductor substrate and a case where main components of the circuit are monolithically integrated, and some resistors or capacitors for adjusting circuit constants may be provided outside the semiconductor substrate.

### Comparative Technology

First, comparative technology will be described, and problems occurring in a conventional operational amplifier will be explained.

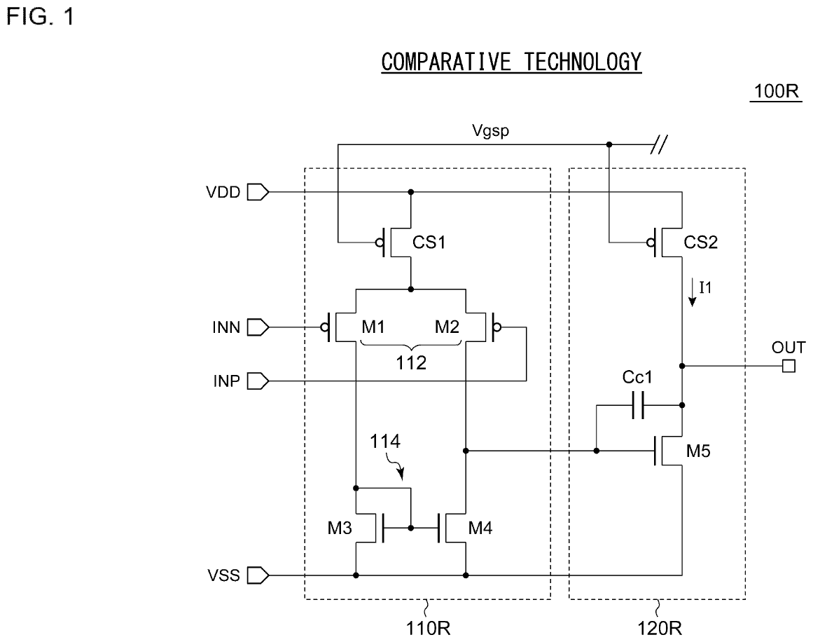

FIG. 1 is a circuit diagram of the operational amplifier 100R according to comparative technology.

The operational amplifier 100R includes an input stage 110R and an output stage 120R. The input stage 110R includes a differential pair 112, a tail current source CS1, and an active load 114. The differential pair 112 includes differential transistors M1 and M2. The tail current source CS1 supplies a tail current to the differential pair 112. The tail current source CS1 includes a PMOS transistor, and a bias voltage Vgsp is supplied to a gate of the PMOS transistor. The bias voltage Vgsp is a gate voltage of a PMOS transistor that is provided on a constant-current path and has its gate and drain short-circuited. The active load 114 includes transistors M3 and M4 forming a current mirror circuit.

The output stage 120R is of class-A type and includes an output transistor M5 and a current source CS2.

The output transistor M5 has its source grounded and receives an output signal of the input stage 110R at its gate.

The output transistor M5 is biased by a current I₁ generated by a current source CS5. A phase-compensation capacitor Cc1 is connected between a gate and a drain of the output transistor M5.

The operational amplifier 100R has a pole (referred to as a first pole ω1) formed by a composite resistance ro1 of resistances rd2 and rd4 of transistors M2 and M4 and the phase-compensation capacitor Cc1. At frequencies higher than the first pole ω1, a gain attenuates at −6 dB/Oct and a phase is delayed by 90 degrees.

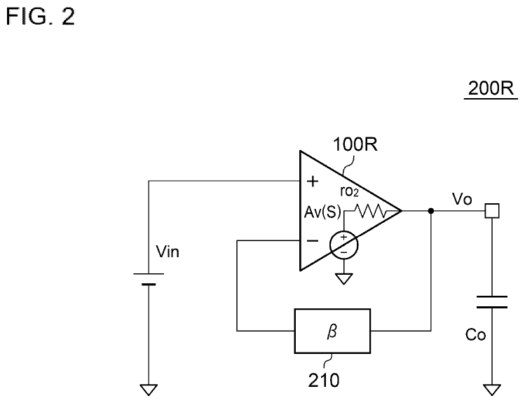

FIG. 2 is a circuit diagram of a non-inverting amplifier 200R using the operational amplifier 100R. The non-inverting amplifier 200R includes the operational amplifier 100R and a feedback circuit 210. β represents a feedback factor of the feedback circuit 210.

When a capacitive load (load capacitance Co) is connected to an output of the non-inverting amplifier 200R, a second pole (a second pole ω2) is formed by the load capacitance Co and an output impedance ro2 of the operational amplifier 100R. At frequencies higher than the second pole ω2, a gain attenuates at −12 dB/Oct and a phase is further delayed by 90 degrees.

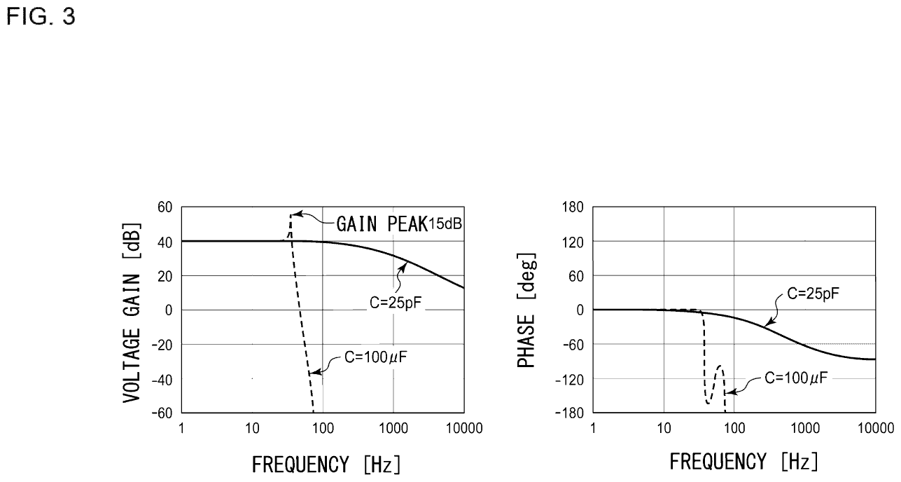

FIG. 3 is a diagram showing frequency characteristics of a gain and a phase of the non-inverting amplifier 200R of FIG. 2. FIG. 3 shows frequency characteristics when 25 pF and 100 μF are connected as a load capacitance Co. As the load capacitance Co increases, a second pole ω2 becomes close to a first pole ω1, which causes a steep gain attenuation and a rapid phase rotation. Then, a gain margin becomes small, and when the Barkhausen oscillation condition is satisfied, the system becomes unstable, which causes oscillation, poor settling, and the like. The load capacitance Co also causes a large gain peak.

In a conventional general operational amplifier 100R, depending on the design, when a load capacitance of several hundred pF to several nF order is connected, the system becomes unstable. Specifically, at power-on, an output voltage oscillates or a time required to settle becomes long.

Hereinafter, an operational amplifier improved in stability against a capacitive load will be described.

### Embodiment

Preferred embodiments will be described below with reference to the drawings. Like or equivalent components, members, and processes shown in the drawings are denoted by like reference numerals, and duplicated descriptions are omitted as appropriate. Further, embodiments are illustrative rather than limiting the present disclosure, and not all features or combinations described in the embodiments are necessarily essential to the disclosure.

In this specification, the expression “member A is connected to member B” includes not only a case in which member A and member B are physically and directly connected but also a case in which member A and member B are indirectly connected via another member that does not substantially affect their electrical connection state or does not impair a function or effect achieved by their coupling.

Similarly, the expression “member C is connected (provided) between member A and member B” includes not only a case in which member A and member C, or member B and member C are directly connected but also a case in which they are indirectly connected via another member that does not substantially affect their electrical connection state or does not impair a function or effect achieved by their coupling.

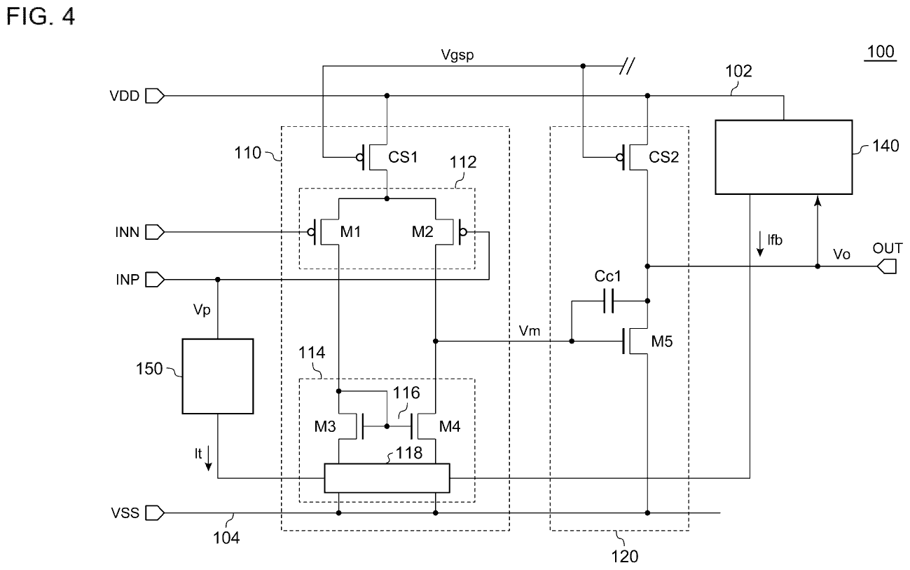

FIG. 4 is a circuit diagram of the operational amplifier 100 according to one embodiment. The operational amplifier 100 includes an input stage 110, an output stage 120, a phase-compensation circuit 140, and an offset-cancellation circuit 150. A power-supply voltage VDD is supplied to a power-supply line 102, and a ground voltage VSS is supplied to a ground line 104.

The input stage 110 includes a differential pair 112, an active load 114, and a tail current source CS1. The differential pair 112 includes differential transistors M1 and M2 that are P-channel MOSFETs (Metal Oxide Semiconductor Field Effect Transistors). The tail current source CS1 includes a PMOS transistor to which a bias voltage Vgsp is supplied so that a constant current flows. Specifically, the bias voltage Vgsp is a gate voltage of a PMOS transistor that is provided on a constant-current path and has its gate and drain short-circuited.

The active load 114 is connected to drains of the differential pair 112. The active load 114 includes a current mirror circuit 116 formed by transistors M3 and M4. An impedance circuit 118 is connected to a source side of the current mirror circuit 116.

The output stage 120 includes an output transistor M5, a current source CS2, and a phase-compensation capacitor Cc1. The output transistor M5 is an N-channel MOSFET, has its source connected to the ground line 104 and its drain connected to the current source CS2. An output voltage Vm of the input stage 110 is supplied to a gate of the output transistor M5.

The phase-compensation circuit 140 generates a feedback current Ifb in accordance with an output voltage Vo of the operational amplifier 100. The phase-compensation circuit 140 feeds back the feedback current Ifb to the active load 114 and changes a balance of the current mirror circuit 116. That is, the phase-compensation circuit 140 performs current-feedback type phase compensation.

The principle of the phase compensation will be described in a frequency domain.

Consider a case in which a non-inverting amplifier as shown in FIG. 2 is configured by using the operational amplifier 100. A closed-loop gain G(s) of the non-inverting amplifier is represented by Equation (1):

G(s)=Vo(s)/Vin(s)=Av(s)/(1+βAv(s)) (1)
where Av(s) is an open-loop gain of the operational amplifier 100, and β is a feedback factor.

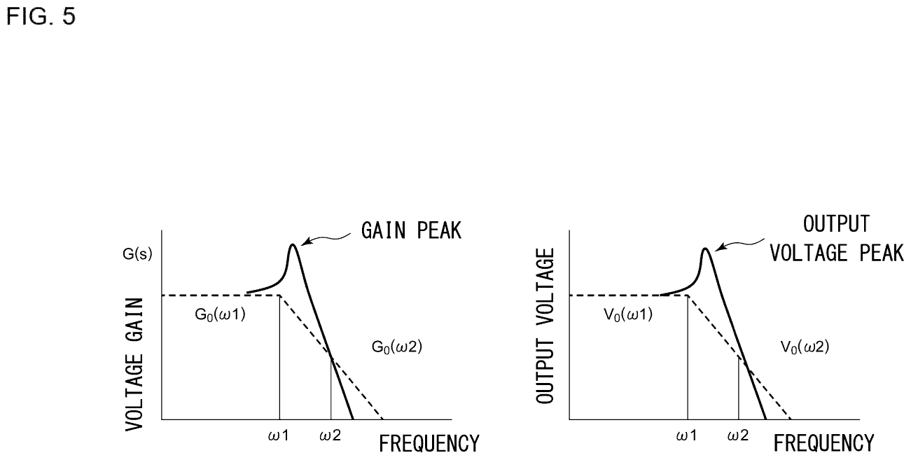

FIG. 5 is a diagram showing frequency characteristics of a conventional non-inverting amplifier.

FIG. 5 shows frequency characteristics of the closed-loop gain G(s) and the output voltage Vo. A broken line indicates the gain G(s) in a no-load condition, whereas a solid line indicates the gain G(s) when a large load capacitance is connected. The non-inverting amplifier has a gain peak due to the load capacitance. When an angular frequency changes from a first pole ω1 to a second pole ω2, the closed-loop gain changes from Go(ω1) to Go(ω2).

By transforming Equation (1), the output voltage Vo(s) is represented by Equation (2):

Vo(s)=Av(s)/(1+βAv(s)) ×Vin(s) (2)
where s=jω.

Assuming that an amplitude of the input voltage Vin is constant, the frequency characteristics of the output voltage Vo(s) follow the frequency characteristics of the closed-loop gain G(s). Accordingly, in the frequency domain, the output voltage Vo(s) has a gain peak, and when the angular frequency changes from ω1 to ω2, the output voltage Vo(s) changes from Vo(ω1) to Vo(ω2).

As can be seen from FIG. 3, a steep gain attenuation and a rapid phase rotation occur in the same frequency band. Therefore, the output voltage Vo(s) represents a variation of the closed-loop gain G(s), and further, can be said to represent the phase rotation.

When the feedback current Ifb is fed back to the active load 114, a gate voltage Vm of the output transistor M5 increases and an output current Io decreases. That is, in the operational amplifier 100, when the feedback current Ifb increases in accordance with a gain peak, negative feedback is applied so that an increase of the output voltage Vo is suppressed.

Thus, according to the operational amplifier 100, a gain peak caused by the load capacitance Co can be suppressed.

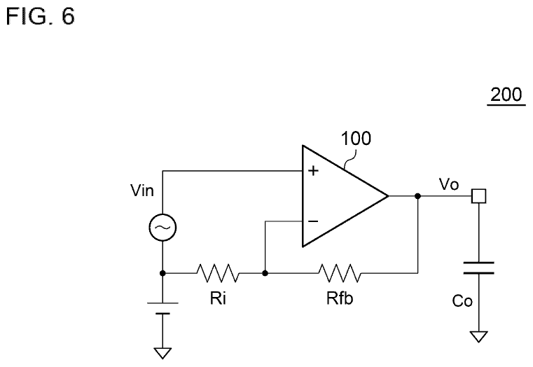

FIG. 6 is a circuit diagram of a non-inverting amplifier 200 using the operational amplifier 100. The non-inverting amplifier 200 includes the operational amplifier 100 and resistors Ri and Rfb.

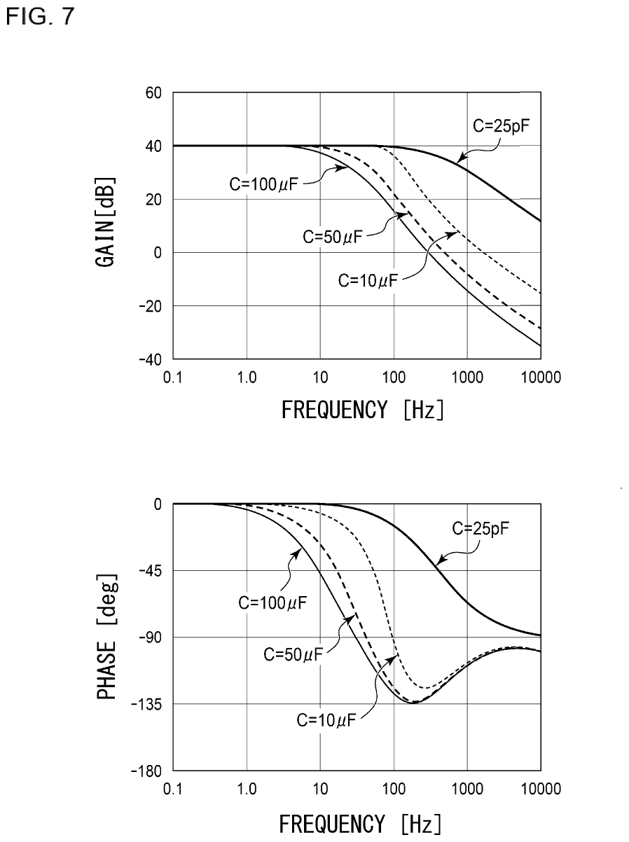

FIG. 7 is a diagram showing frequency characteristics of the non-inverting amplifier 200 of FIG. 6. The frequency characteristics are calculated with Ri=1 kΩ and Rfb=100 kΩ.

As shown in FIG. 3, in the conventional technology, a gain peak occurred in gain characteristics when a large load capacitance Co was connected. In contrast, when using the operational amplifier 100 according to the embodiment, the gain peak can be suppressed. Focusing on phase characteristics, while a steep phase rotation occurred due to the load capacitance Co in the conventional technology, in the embodiment, even when a large load capacitance of 100 μF is connected, a phase delay is suppressed to 135 degrees, ensuring a sufficient phase margin.

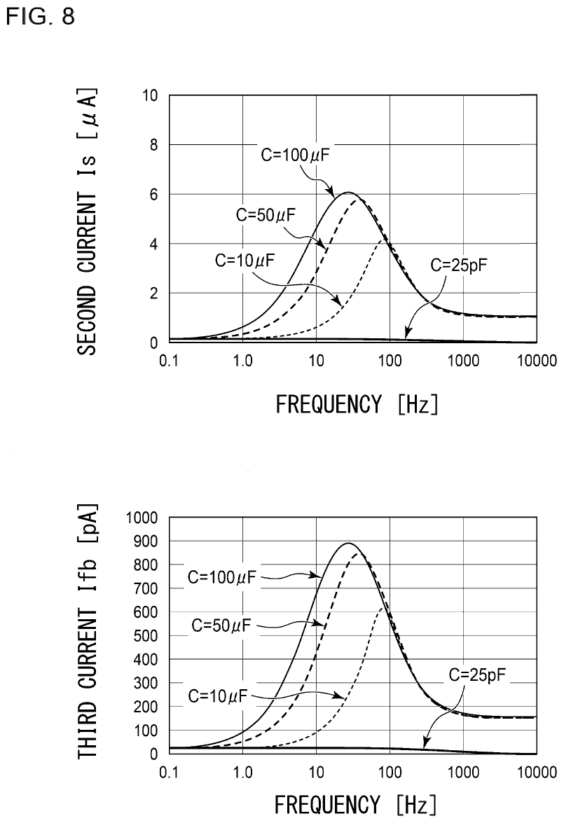

FIG. 8 is a diagram showing frequency characteristics of a second current Is and a third current Ifb. It is understood that the second current Is and the third current Ifb have the same frequency characteristics.

An amount of the third current Ifb only needs to be appropriately designed so that suitable phase compensation is obtained.

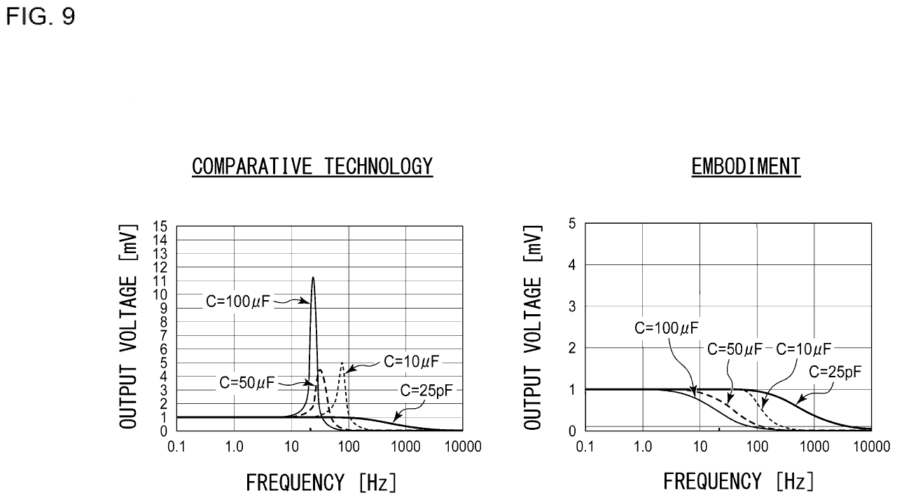

FIG. 9 is a diagram showing frequency characteristics of output voltages of a non-inverting amplifier according to comparative technology and a non-inverting amplifier according to the embodiment. In the comparative technology, a gain peak occurs depending on a load capacitance, whereas in the embodiment, it is seen that the gain peak is suppressed regardless of the magnitude of the load capacitance.

Returning to FIG. 4. As described above, the feedback current Ifb generated by the output-voltage monitoring circuit 130 includes not only an AC component Ifb(ac) where a gain peak occurs, but also a DC component Ifb(dc). This DC component Ifb(dc) causes a DC offset in the operational amplifier 100.

The offset-cancellation circuit 150 is provided to suppress this DC offset.

The offset-cancellation circuit 150 supplies a correction current It to the impedance circuit 118 of the input stage 110 in accordance with an input voltage (common-mode input voltage) Vp of the operational amplifier.

The correction current It is supplied to the impedance circuit 118 so as to cancel the feedback current Ifb generated by the phase-compensation circuit 140.

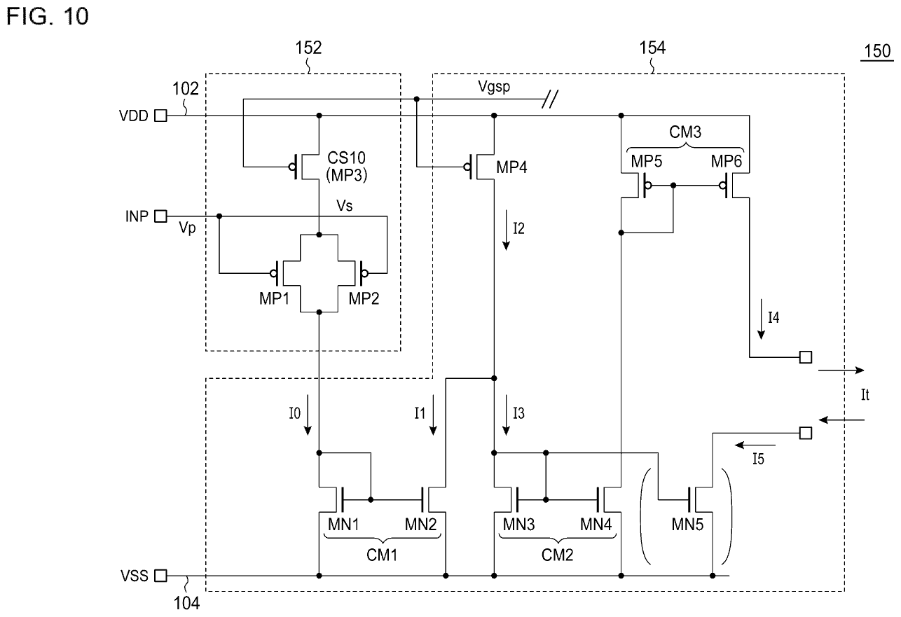

FIG. 10 is a circuit diagram of the offset-cancellation circuit 150 according to one embodiment. The offset-cancellation circuit 150 includes a common-mode voltage detection circuit 152 and a correction current generation circuit 154. The common-mode voltage detection circuit 152 converts the input voltage Vp of the operational amplifier 100 into a current signal I₀.

The common-mode voltage detection circuit 152 includes MOS transistors MP1 and MP2 that are of the same type as the differential pair 112 of the operational amplifier 100 (PMOS transistors in this example). Sources of the MOS transistors MP1 and MP2 are commonly connected to each other and drains of MP1 and MP2 are commonly connected to each other. A voltage Vp at a non-inverting input terminal (INP) of the operational amplifier 100 is applied to gates of MP1 and MP2.

A current source CS10 is connected to the sources of MOS transistors MP1 and MP2. Sizes of MOS transistors MP1 and MP2 are equal to sizes of the differential pair 112, and the current source CS10 generates a current equal to that of the tail current source CS1. The current source CS10 includes a PMOS transistor MP3. A bias voltage Vgsp, common to the tail current source CS1, is supplied to a gate of the PMOS transistor MP3.

When an input voltage Vp (a common-mode input voltage) changes, a source voltage Vs of MOS transistors MP1 and MP2, in other words, a drain-to-source voltage of the PMOS transistor MP3, changes. Due to a channel-length modulation effect, a current I₀ flowing through the PMOS transistor MP3 changes with respect to the input voltage Vp with a substantially constant slope.

The correction current generation circuit 154 generates a correction current It in accordance with the current I₀. The correction current It changes with respect to the input voltage Vp with a substantially constant slope.

The correction current generation circuit 154 includes current mirror circuits CM1, CM2, and CM3, and a current source CS11. The current source CS11 generates a constant current I₂. The current source CS11 includes a PMOS transistor MP4. A bias voltage Vgsp is supplied to a gate of the PMOS transistor MP4. A size (W/L) of the PMOS transistor MP4 is equal to a size (W/L) of the PMOS transistor MP3.

The current mirror circuit CM1 includes NMOS transistors MN1 and MN2. The current mirror circuit CM1 mirrors the current I₀ and outputs a current I₁.

The current mirror circuit CM2 mirrors a difference current I₃ between the currents I₂ and I₁. The current mirror circuit CM2 includes NMOS transistors MN3 and MN4. The current mirror circuit CM3 mirrors an output current of the current mirror circuit CM2 and outputs a current I₄. The current I₄ is proportional to the current I₃:

I₄=I₃×γ₁
γ₁ is a constant determined by mirror ratios (current gains) of the current mirror circuits CM2 and CM3. The correction current generation circuit 154 can source the current I₄, proportional to the current I₃, as the correction current It to the active load 114.

Instead of, or in addition to, transistors MN4, MP5, and MP6, an NMOS transistor MN5 may be provided. The NMOS transistor MN5, together with the NMOS transistor MN3, constitutes the current mirror circuit CM2, and a current I₅ proportional to the current I₃ flows through the NMOS transistor MN5:

I₅=I₃×γ₂
γ₂ is a constant determined by a mirror ratio (current gain) of the current mirror circuit CM2. The correction current generation circuit 154 can sink the current I₅, proportional to the current I₃, as the correction current It from the active load 114.

One or both of the currents I₄ and I₅ may be selected depending on a configuration of the input stage 110.

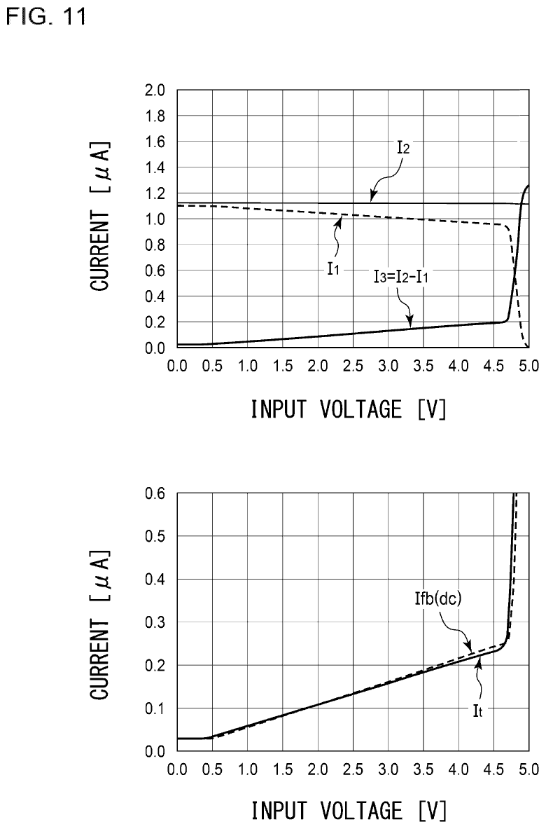

FIG. 11 is a diagram illustrating an operation of the offset-cancellation circuit 150 of FIG. 10. The upper graph shows currents I₁ to I₃ with respect to the input voltage. The current I₁ has a negative slope with respect to the input voltage Vp, whereas the current I₃ has a positive slope with respect to the input voltage Vp and linearly increases with a constant slope as the input voltage Vp increases.

A lower graph of FIG. 11 shows a relationship between the correction current It and a DC component Ifb(dc) of the third current Ifb generated by the phase-compensation circuit 140. By appropriately setting the current gain γ₁ of the correction current generation circuit 154, an influence of the DC component Ifb(dc) of the third current Ifb can be canceled. Thus, an offset voltage of the operational amplifier 100 can be suppressed.

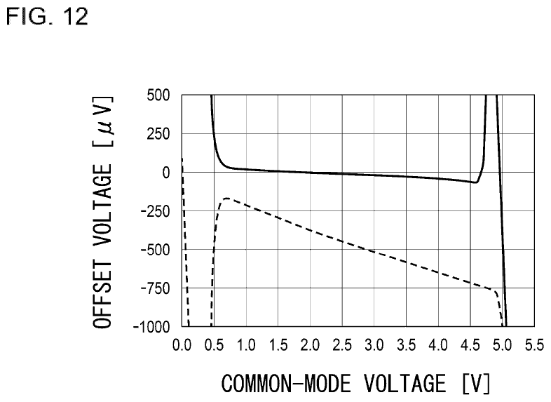

FIG. 12 is a diagram showing a relationship between a common-mode input voltage of a non-inverting amplifier and an offset voltage. A solid line indicates characteristics of a non-inverting amplifier using the operational amplifier 100 of FIG. 4. For comparison, characteristics of a non-inverting amplifier using an operational amplifier without the offset-cancellation circuit 150 are indicated by a broken line. By providing the offset-cancellation circuit 150, the offset voltage depending on the input voltage can be brought close to 0 V.

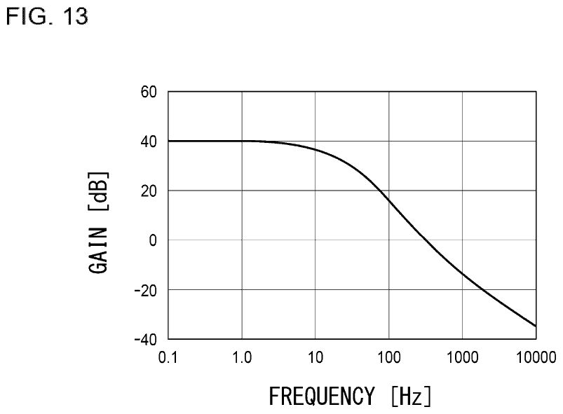

FIG. 13 is a diagram showing frequency characteristics of a non-inverting amplifier using an operational amplifier. A solid line indicates characteristics of the non-inverting amplifier using the operational amplifier 100 of FIG. 4. For comparison, a broken line indicates characteristics of a non-inverting amplifier using an operational amplifier without the offset-cancellation circuit 150. A load capacitance of 100 μF is connected to the non-inverting amplifier. No degradation in frequency characteristics is observed due to addition of the offset-cancellation circuit 150.

Thus, according to the operational amplifier 100 of FIG. 4, the stability against a large load capacitance can be improved while suppressing an offset voltage.

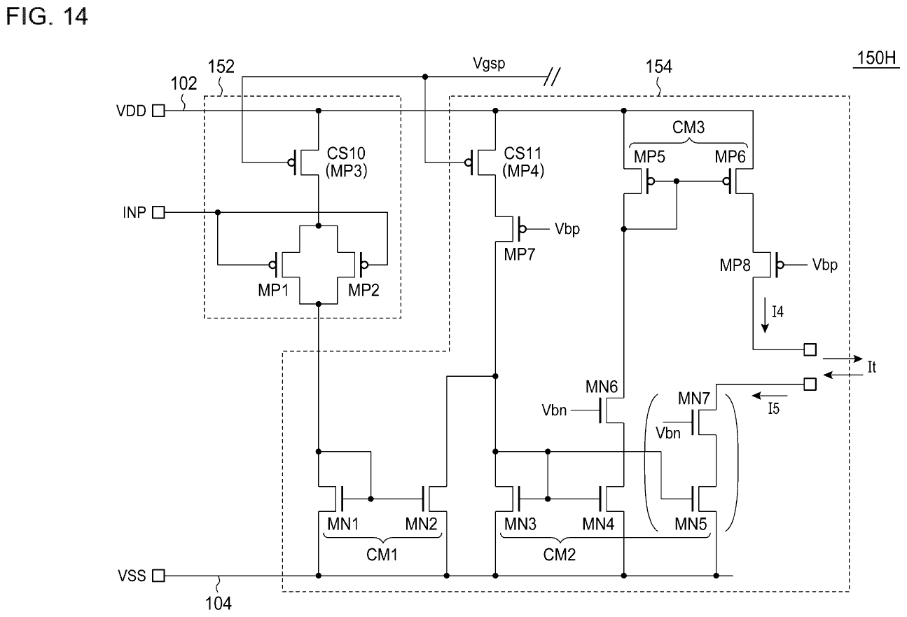

FIG. 14 is a circuit diagram of an offset-cancellation circuit 150H according to a first modification.

The offset-cancellation circuit 150H is different from the configuration of the correction current generation circuit 154 in FIG. 10. Specifically, PMOS transistors MP7 and MP8 and NMOS transistors MN6 and MN7, which are cascode elements, are added in the correction current generation circuit 154 of FIG. 14. Appropriate bias voltages Vbp or Vbn are supplied to gates of respective MOS transistors.

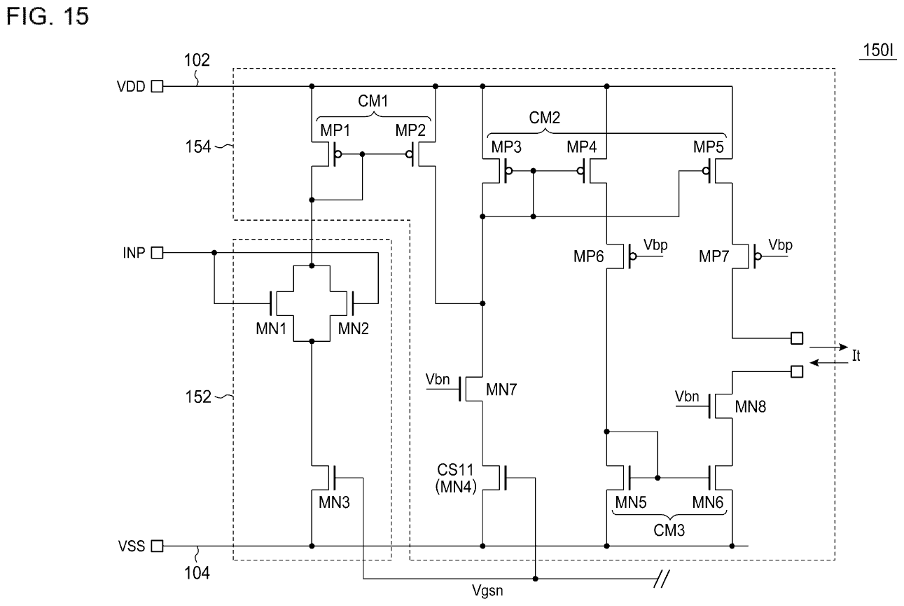

FIG. 15 is a circuit diagram of an offset-cancellation circuit 150I according to a second modification.

The offset-cancellation circuit 150I is obtained by replacing PMOS transistors of the offset-cancellation circuit 150H of FIG. 14 with NMOS transistors, replacing NMOS transistors with PMOS transistors, and reversing power supply rails (VDD and VSS).

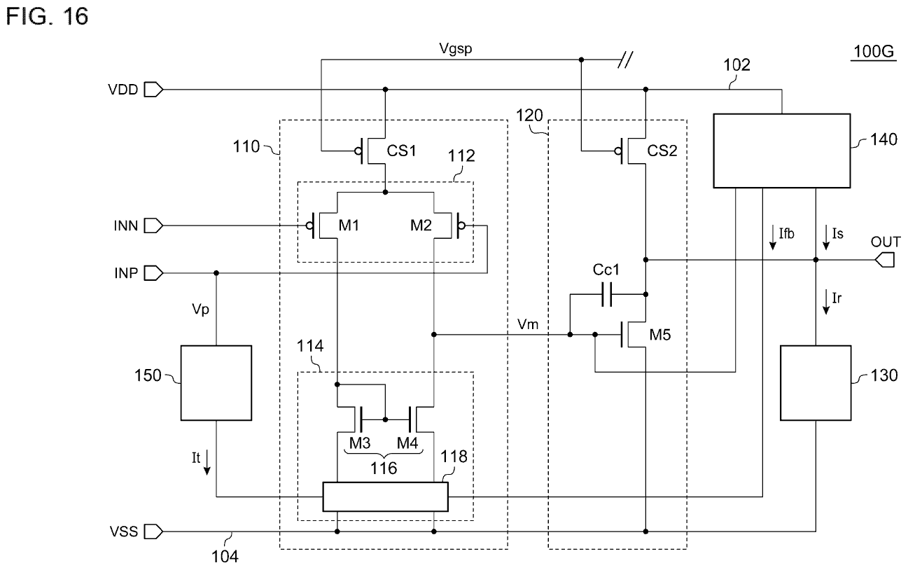

FIG. 16 is a circuit diagram of an operational amplifier 100G according to one embodiment. The operational amplifier 100G further includes an output-voltage monitoring circuit 130 in addition to the operational amplifier 100 of FIG. 4.

The output-voltage monitoring circuit 130 generates a current (referred to as a first current Ir) in accordance with an output voltage Vo of the operational amplifier 100. The output-voltage monitoring circuit 130 can be considered as a V/I (voltage-to-current) conversion circuit having 1/Ro as a conversion gain, and a relationship between the first current Ir and the output voltage Vo is represented by the following expression:

Ir=Vo/Ro
The first current Ir may include an AC component and a DC component of the output voltage Vo. However, for simplification of the description, the DC component is ignored, and the first current Ir can be regarded as representing a variation of the output voltage Vo, i.e., an AC component of the output voltage Vo.

A gate voltage Vm of the output transistor M5, in other words, an output voltage Vm of the input stage 110, is input to the phase-compensation circuit 140. The phase-compensation circuit 140 generates a second current Is in accordance with the gate voltage Vm of the output transistor M5 and supplies the second current Is to an output terminal OUT of the operational amplifier 100.

As will be described in detail later, the second current Is is a current corresponding to the first current Ir and therefore is a current responsive to variations (AC components) of the output voltage Vout.

The phase-compensation circuit 140 also generates a third current Ifb in accordance with the second current Is, that is, in accordance with a variation of the output voltage Vo. The phase-compensation circuit 140 feeds back the third current Ifb to the active load 114 as the above-described feedback current Ifb and changes a balance of the current mirror circuit 116. Namely, the phase-compensation circuit 140 performs current-feedback type phase compensation.

A first current Ir(s) flowing through the output-voltage monitoring circuit 130 is represented by:

Ir(s)=(1/Ro)×Vo(s)

As described above, since the output voltage Vo(s) follows a closed-loop gain G(s) of the non-inverting amplifier 200, the first current Ir(s) also follows the closed-loop gain G(s) of the non-inverting amplifier 200.

As can be seen from FIG. 3, a steep gain attenuation and a rapid phase rotation occur in the same frequency band. Accordingly, the first current Ir(s) represents a variation of the closed-loop gain G(s) and, furthermore, can be said to represent the phase rotation.

When the first current Ir(s) increases, an output current Io of the output stage 120 increases. When a bias current of the output stage 120 is Ib and a drain current of the output transistor M5 is Im5, a relationship Io=Ib−Im5 holds. Accordingly, as the first current Ir(s) increases, the drain current Im5 decreases, and as the first current Ir(s) decreases, the drain current Im5 increases.

A drain current Im5 of the output transistor M5 increases as a gate voltage Vm becomes higher and decreases as the gate voltage Vm becomes lower. The phase-compensation circuit 140 generates the second current Is that follows a change in the output current Io of the input stage 110 based on the gate voltage Vm of the output transistor M5. Namely, since the second current Is has a current amount corresponding to the first current Ir, a part or all of the first current Ir is canceled by the second current Is.

Further, the phase-compensation circuit 140 generates the third current Ifb in accordance with the second current Is. The third current Ifb also has a current amount corresponding to the first current Ir. As described above, the first current Ir represents the closed-loop gain G(s) of the non-inverting amplifier 200.

When the third current Ifb is fed back to the active load 114, the gate voltage Vm of the output transistor M5 increases and the output current Io decreases. That is, in the operational amplifier 100, when a gain peak is detected by the output-voltage monitoring circuit 130, the third current Ifb applies negative feedback so that the rise of the output voltage Vo is suppressed.

In such a configuration, by adding the offset-cancellation circuit 150, an offset voltage caused by a DC component of the feedback current Ifb can be reduced.

The present disclosure extends to various devices and methods that can be understood from the circuit diagram of FIG. 4 or derived from the above description, and is not limited to the specific configurations. In the following, more concrete configuration examples and embodiments will be described in order to assist understanding of the essence and operation of the present disclosure and to clarify them, but not to narrow the scope of the present disclosure.

### Embodiment 1

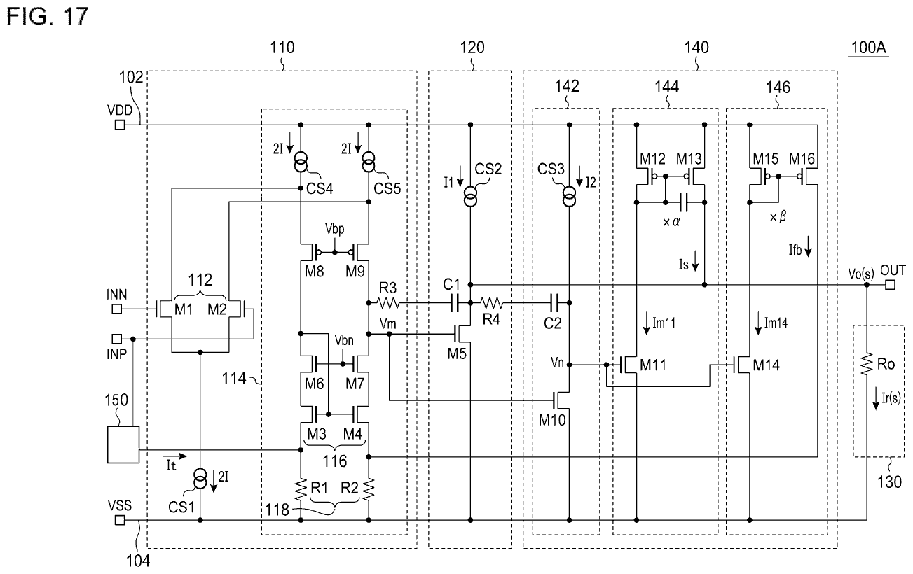

FIG. 17 is a circuit diagram of an operational amplifier 100A according to Embodiment 1. The operational amplifier 100A is a folded-cascode operational amplifier.

A differential pair 112 of the input stage 110 includes N-channel MOSFETs (PMOS transistors) M1 and M2. In addition to NMOS transistors M3 and M4 forming a current mirror circuit 116 and resistors R1 and R2 forming an impedance circuit 118, the active load 114 further includes current sources CS4 and CS5, NMOS transistors M6 and M7, and PMOS transistors M8 and M9. A gate of each NMOS transistor M6 and M7 is supplied with a bias voltage Vbn generated by a bias circuit (not shown), and a gate of each PMOS transistor M8 and M9 is supplied with a bias voltage Vbp generated by a bias circuit (not shown).

The output stage 120 is an A-class output stage and includes an output transistor M5 and a current source CS2. A capacitor C1 and a resistor R3 constitute a phase-compensation circuit.

The output-voltage monitoring circuit 130 includes a resistor Ro connected between an output terminal OUT and the ground line 104. The output-voltage monitoring circuit 130 sinks a first current Ir represented by Ir=Vo/Ro.

The phase-compensation circuit 140 includes a replica output stage 142, a second current generation section 144, and a third current generation section 146. The replica circuit 142 includes a transistor M10 (called a replica transistor) and a current source CS3 and has the same circuit configuration as the output stage 120. A gate of the transistor M10 receives the same voltage Vm as a gate voltage Vm of the output transistor M5. Accordingly, the replica circuit 142 operates in the same manner as the output stage 120. The replica circuit 142 outputs a drain voltage Vn of the transistor M10.

The second current generation section 144 includes an NMOS transistor M11 and PMOS transistors M12 and M13. A gate of the NMOS transistor M11 receives the output voltage Vn of the replica circuit 142. The PMOS transistors M12 and M13 form a current mirror circuit, fold back a current Im11 flowing through the NMOS transistor M11 and generate the second current Is by multiplying the current Im11 by a constant (α times).

The third current generation section 146 is configured in the same manner as the second current generation section 144. Specifically, the third current generation section 146 includes an NMOS transistor M14 and PMOS transistors M15 and M16. A gate of the NMOS transistor M14 receives the output voltage Vn of the replica circuit 142. The PMOS transistors M15 and M16 form a current mirror circuit, fold back a current Im14 flowing through the NMOS transistor M14, and generate the third current Ifb by multiplying the current Im14 by a constant (β times). Preferably, the second current generation section 144 is configured such that a current-gain factor β is adjustable.

Specifically, a gate width-to-length ratio (W/L) of the transistor M16 may be adjustable.

The third current Ifb is supplied to the impedance circuit 118. Specifically, the third current Ifb is supplied to a node connecting a source of the NMOS transistor M4 and the resistor R2.

When the third current Ifb is sourced to a source node of the transistor M4 of the current mirror circuit 116, a correction current It is sourced to a source node of the transistor M3 of the current mirror circuit 116.

The configuration of the operational amplifier 100A has been described above. Next, operation thereof will be described.

Let resistance values of the resistors R1 and R2 be equal to R. Gate voltages Vg of the transistors M3 and M4 are expressed as follows:

Vg=Vgs3+I·R

Vg=Vgs4+(I+Ifb)·R
where Vgs3 represents a gate-to-source voltage of the transistor M3 and Vgs4 represents a gate-to-source voltage of the transistor M4.

Since the transistors M3 and M4 form a current mirror circuit, when the third current Ifb is not present, Vgs3 =Vgs4 holds. However, when the third current Ifb is non-zero, the following relationship is established:

Vgs4=Vgs3−Ifb×R

That is, the gate-to-source voltage Vgs4 of the transistor M4 becomes smaller due to the third current Ifb fed back thereto. In other words, when a gain peak occurs at a certain frequency ω and the third current Ifb flows, the gate-to-source voltage Vgs4 of the transistor M4 decreases, and a negative feedback is applied. As a result, the gate voltage Vm5 of the output transistor M5 increases, and the output current Io of the output stage 120 decreases, thereby canceling an increase in the output voltage Vo due to the gain peak.

It is noted that the frequency characteristics shown in FIG. 7 were calculated using the operational amplifier 100A of FIG. 17.

### Embodiment 2

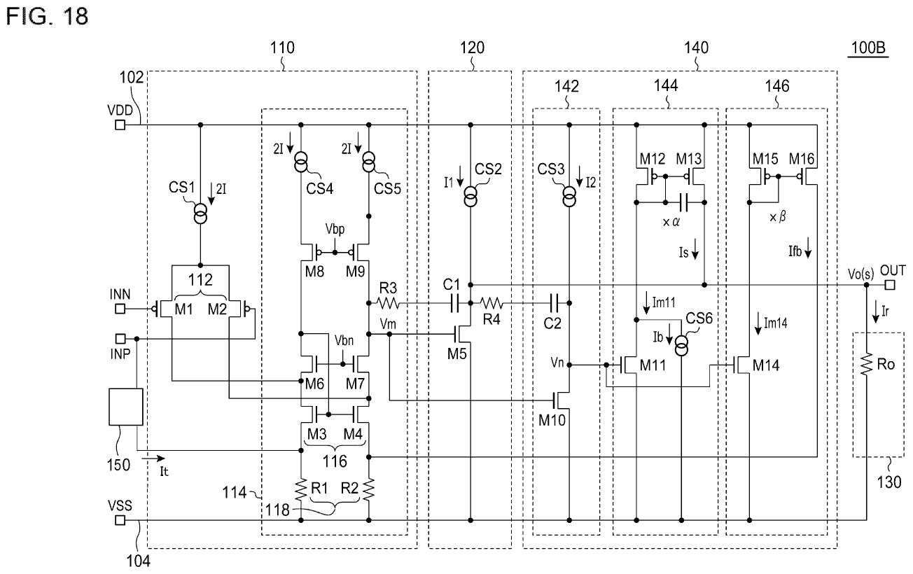

FIG. 18 is a circuit diagram of an operational amplifier 100B according to Embodiment 2. In Embodiment 1, the differential pair 112 (M1 and M2) of the input stage 110 was formed of NMOS transistors. In Embodiment 2, however, the differential pair is formed of PMOS transistors. The active load 114, the replica circuit 142, and the third current generation section 146 are the same as those of FIG. 17. A current source CS6 for sinking a constant current Ib is additionally provided in the second current generation section 144.

Thus, the configuration of the operational amplifier does not depend on whether it is a P-input type or an N-input type.

### Embodiment 3

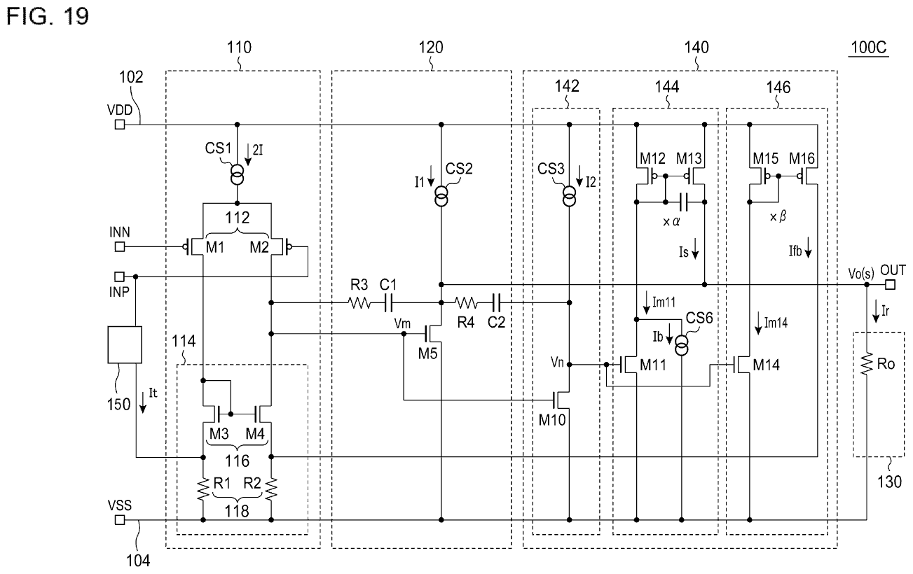

FIG. 19 is a circuit diagram of an operational amplifier 100C according to Embodiment 3. FIGS. 17 and 18 show folded-cascode operational amplifiers, whereas in FIG. 19, the active load 114 is constituted by a current-mirror load. As in FIG. 18, the differential pair 112 is formed of PMOS transistors, and the active load 114 is additionally provided with the current source CS6.

### Embodiment 4

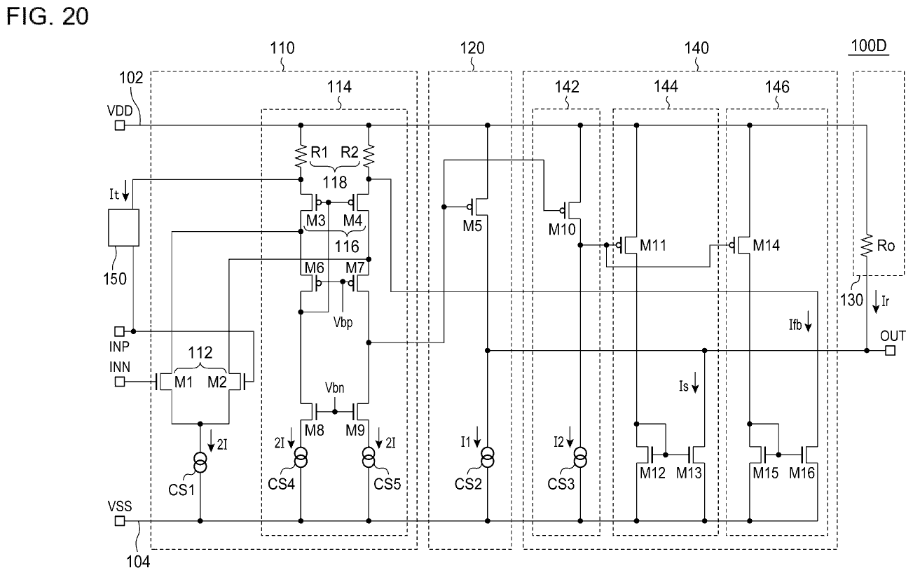

FIG. 20 is a circuit diagram of an operational amplifier 100D according to Embodiment 4. The operational amplifier 100D is obtained by replacing the PMOS transistors of the operational amplifier 100A in FIG. 17 with NMOS transistors, replacing the NMOS transistors with PMOS transistors, and inverting the supply rails (VDD and VSS). Note that the phase-compensation elements are omitted from illustration.

When the third current Ifb is sunk from a source node of the transistor M4 of the current mirror circuit 116, the correction current It is sunk from a source node of the transistor M3 of the current mirror circuit 116.

### Embodiment 5

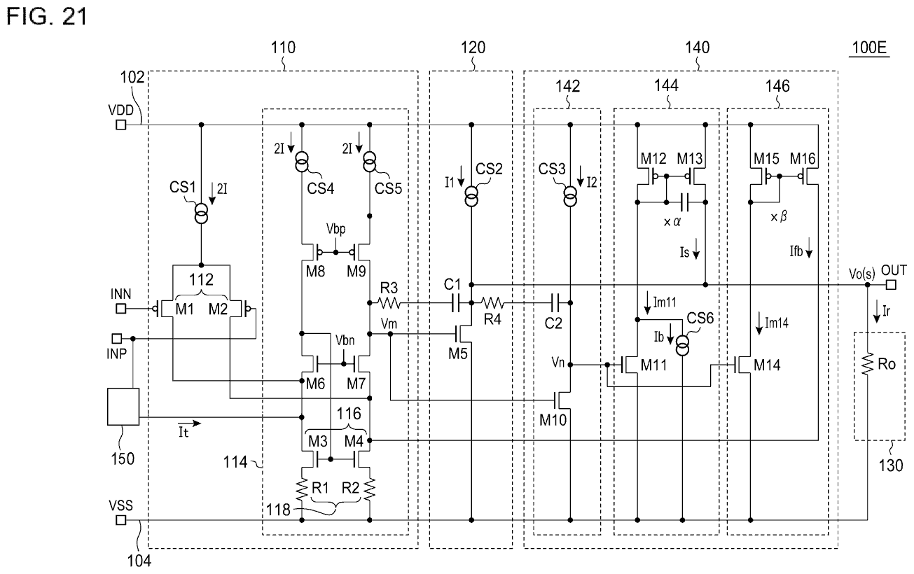

FIG. 21 is a circuit diagram of an operational amplifier 100E according to Embodiment 5. The operational amplifier 100E is configured similarly to the operational amplifier 100B of FIG. 18. A difference from FIG. 18 lies in a supply destination of the third current Ifb generated by the third current generation section 146. In FIG. 21, the third current Ifb is supplied to a drain side of the transistor M4 forming the current mirror circuit 116.

As shown in FIG. 21, when the third current Ifb is sourced to a drain node of the transistor M4 of the current mirror circuit 116, the correction current It is sourced to a drain node of the transistor M3 of the current mirror circuit 116.

### Embodiment 6

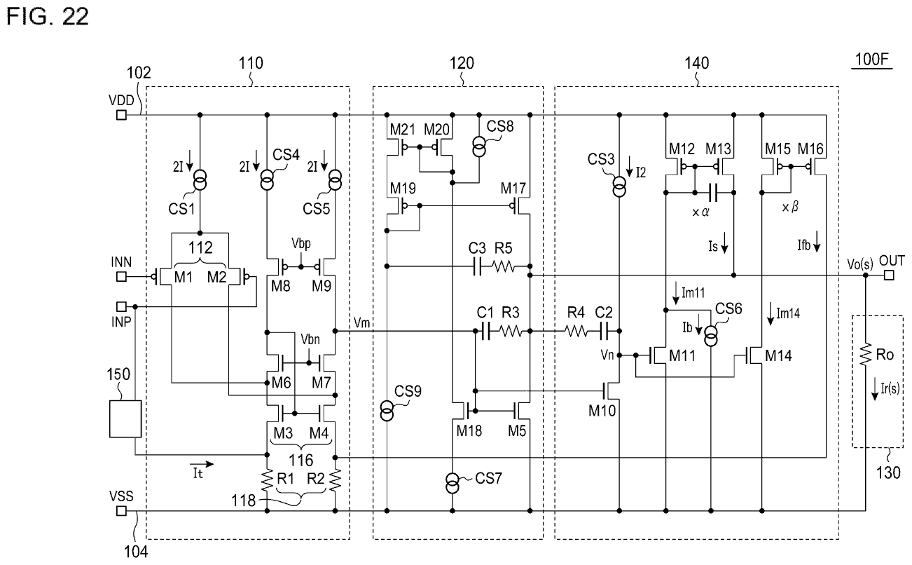

FIG. 22 is a circuit diagram of an operational amplifier 100F according to Embodiment 6. In the above description, A-class operational amplifiers have been described. However, the technology according to the present disclosure is also applicable to AB-class operational amplifiers. The configurations of the input stage 110 and the phase-compensation circuit 140 are the same as those in FIG. 18, while the configuration of the output stage 120 is different from that in FIG. 18.

The output stage 120 is similar to a general AB-class output stage, and includes, in addition to the output transistor M5, transistors M17 to M21 and current sources CS7, CS8, and CS9. Further, for phase compensation, the output stage includes capacitors C1 and C3, and resistors R3 and R5.

The embodiments merely illustrate the principles and applications of the present disclosure, and numerous modifications and variations of arrangement are allowed within the scope not departing from the spirit of the present disclosure as defined by the claims.

### Appendix

The techniques disclosed in this specification can be understood in one aspect as follows.

Item 1. An operational amplifier comprising:
an input stage having a differential pair, a tail current source, and an active load;
an output stage including an output transistor coupled to receive an output signal of the input stage;
a phase-compensation circuit structured to supply a feedback current to the active load in accordance with an output voltage of the operational amplifier; and
an offset-cancellation circuit structured to supply a correction current to the active load in accordance with an input voltage of the operational amplifier.

Item 2. The operational amplifier according to item 1, wherein the active load includes:
a current mirror circuit; and
a pair of resistors connected to sources of the current mirror circuit;
wherein the feedback current is supplied to a source node of one transistor of the current mirror circuit, and the correction current is supplied to a source node of another transistor of the current mirror circuit.

Item 3. The operational amplifier according to Item 1, wherein the active load comprises:
a current mirror circuit; and
a pair of resistors connected to sources of the current mirror circuit;
wherein the feedback current is supplied to a drain node of one transistor of the current mirror circuit, and the correction current is supplied to a drain node of another transistor of the current mirror circuit.

Item 4. The operational amplifier according to any one of Items 1 to 3, wherein the offset-cancellation circuit comprises:
a common-mode voltage detection circuit structured to convert an input voltage of the operational amplifier into a current signal; and
a correction-current generation circuit structured to generate the correction current in accordance with the current signal.

Item 5. The operational amplifier according to Item 4, wherein the common-mode voltage detection circuit comprises:
a first MOS transistor and a second MOS transistor, having their gates coupled to an input terminal of the operational amplifier, and having their sources connected to each other and their drains connected to each other; and
a third MOS transistor, having its source connected to the sources of the first and second MOS transistors and having its gate supplied with a bias voltage common to the tail current source.

Item 6. The operational amplifier according to Item 5, wherein the correction-current generation circuit comprises:
a current mirror circuit having its input connected to drains of the first MOS transistor and the second MOS transistor, the current mirror circuit being structured to mirror and output a current flowing through the third MOS transistor; and
a constant-current source;
wherein the correction current is based on a difference between a current generated by the constant-current source and an output current of the current mirror circuit.

Item 7. The operational amplifier according to any one of Items 1 to 6, further comprising an output-variation detection circuit connected to an output terminal of the operational amplifier and structured to generate a first current in accordance with an output voltage generated at the output terminal,

wherein the phase-compensation circuit is structure to supply a second current to the output terminal in accordance with a gate voltage of the output transistor, and to supply a third current as the feedback current to the active load in accordance with the second current.

Item 8. The operational amplifier according to Item 7, wherein the phase-compensation circuit is structured to be capable of adjusting an amount of the third current relative to an amount of the second current.

Item 9. The operational amplifier according to Item 7 or 8, wherein the phase-compensation circuit comprises:
a replica transistor of the same type as the output transistor, having its gate coupled to a gate of the output transistor and having its source grounded; and
a current source having its output coupled to a drain of the replica transistor;
wherein the second current and the third current are generated in accordance with a drain voltage of the replica transistor.

Item 10. The operational amplifier according to Item 9, wherein the phase-compensation circuit comprises:
a first transistor having its gate supplied with a drain voltage of the replica transistor and having its source grounded; and
a first current mirror circuit having its input coupled to a drain of the first transistor to mirror a current flowing through the first transistor and generate the second current.

Item 11. The operational amplifier according to Item 7 or 8, wherein the phase-compensation circuit comprises:
a second transistor having its gate supplied with a drain voltage of the replica transistor and having its source grounded; and
a second current mirror circuit having its input coupled to a drain of the second transistor to mirror a current flowing through the second transistor and generate the third current.

Item 12. The operational amplifier according to any one of Items 7 to 11, wherein the output-voltage monitoring circuit comprises a resistor disposed between the output terminal of the operational amplifier and a ground line, or between the output terminal of the operational amplifier and a power-supply line.

Item 13. The operational amplifier according to any one of Items 1 to 12, which is monolithically integrated on a single semiconductor substrate.

What is claimed is:

1. An operational amplifier comprising:
an input stage having a differential pair, a tail current source, and an active load;
an output stage including an output transistor coupled to receive an output signal of the input stage;
a phase-compensation circuit structured to supply a feedback current to the active load in accordance with an output voltage of the operational amplifier; and
an offset-cancellation circuit structured to supply a correction current to the active load in accordance with an input voltage of the operational amplifier.

2. The operational amplifier according to claim 1, wherein the active load includes:
a current mirror circuit; and
a pair of resistors connected to sources of the current mirror circuit;
wherein the feedback current is supplied to a source node of one transistor of the current mirror circuit, and the correction current is supplied to a source node of another transistor of the current mirror circuit.

3. The operational amplifier according to claim 1, wherein the active load comprises:
a current mirror circuit; and
a pair of resistors connected to sources of the current mirror circuit;
wherein the feedback current is supplied to a drain node of one transistor of the current mirror circuit, and the correction current is supplied to a drain node of another transistor of the current mirror circuit.

4. The operational amplifier according to claim 1, wherein the offset-cancellation circuit comprises:
a common-mode voltage detection circuit structured to convert an input voltage of the operational amplifier into a current signal; and
a correction-current generation circuit structured to generate the correction current in accordance with the current signal.

5. The operational amplifier according to claim 4, wherein the common-mode voltage detection circuit comprises:
a first MOS transistor and a second MOS transistor, having their gates coupled to an input terminal of the operational amplifier, and having their sources connected to each other and their drains connected to each other; and
a third MOS transistor, having its source connected to the sources of the first and second MOS transistors and having its gate supplied with a bias voltage common to the tail current source.

6. The operational amplifier according to claim 5, wherein the correction-current generation circuit comprises:
a current mirror circuit having its input connected to drains of the first MOS transistor and the second MOS transistor, the current mirror circuit being structured to mirror and output a current flowing through the third MOS transistor; and
a constant-current source;
wherein the correction current is based on a difference between a current generated by the constant-current source and an output current of the current mirror circuit.

7. The operational amplifier according to claim 1, further comprising an output-variation detection circuit connected to an output terminal of the operational amplifier and structured to generate a first current in accordance with an output voltage generated at the output terminal,
wherein the phase-compensation circuit is structure to supply a second current to the output terminal in accordance with a gavoltage of the output transistor, and to supply a third current as the feedback current to the active load in accordance with the second current.

8. The operational amplifier according to claim 7, wherein the phase-compensation circuit is structured to be capable of adjusting an amount of the third current relative to an amount of the second current.

9. The operational amplifier according to claim 7, wherein the phase-compensation circuit comprises:
a replica transistor of the same type as the output transistor, having its gate coupled to a gate of the output transistor and having its source grounded; and
a current source having its output coupled to a drain of the replica transistor;
wherein the second current and the third current are generated in accordance with a drain voltage of the replica transistor.

10. The operational amplifier according to claim 9, wherein the phase-compensation circuit comprises:
a first transistor having its gate supplied with a drain voltage of the replica transistor and having its source grounded; and
a first current mirror circuit having its input coupled to a drain of the first transistor to mirror a current flowing through the first transistor and generate the second current.

11. The operational amplifier according to claim 7, wherein the phase-compensation circuit comprises:
a second transistor having its gate supplied with a drain voltage of the replica transistor and having its source grounded; and
a second current mirror circuit having its input coupled to a drain of the second transistor to mirror a current flowing through the second transistor and generate the third current.

12. The operational amplifier according to claim 7, wherein the output-voltage monitoring circuit comprises a resistor disposed between the output terminal of the operational amplifier and a ground line, or between the output terminal of the operational amplifier and a power-supply line.

13. The operational amplifier according to claim 1, which is monolithically integrated on a single semiconductor substrate.
